(19) United States
(12) Patent Application Publication
(10) Pub. No.: US 2005/0236623 A1
(43) Pub. Date: Oct. 27, 2005

(54) Semiconductor device

(75) Inventors: Kazushige Takechi, Tokyo (JP); Hiroshi Kanou, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION

(21) Appl. No.: 11/111,762

(22) Filed: Apr. 22, 2005

(30) Foreign Application Priority Data
Apr. 23, 2004 (JP) 2004-128957

(51) Int. Cl. H01L 29/10

(52) U.S. Cl. 257/66

(57) ABSTRACT

An integrated circuit is formed on a flexible substrate by using an amorphous semiconductor thin film, or a polycrystalline or a monocrystalline semiconductor thin film crystallized by laser annealing. A plurality of such flexible integrated circuit boards and mounted on a separate support substrate. This can enhance the mechanical strength of devices, such as an IC card and a liquid crystal display, and allow those devices to be manufactured at a low cost. It is also possible to provide a semiconductor device with a higher performance, on which a flexible integrated circuit board and an IC chip made from a silicon and/or glass wafer. Adhering a film substrate having a high thermal conductivity, such as a metal, to the bottom side of the flexible integrated circuit board improves the heat discharging characteristic of the integrated circuit and suppress the problem of self-heating.

### BACKGROUND OF THE INVENTION

1. Field of the Invention

The present invention relates to a semiconductor device which has a plurality of integrated circuit boards mounted on a support substrate, and, more particularly, to a semiconductor device on which a plurality of flexible integrated circuit boards having different functions are mounted.

2. Description of the Related Art

Recently, there is an increasing demand for IC cards incorporating a memory circuit or a microprocessor circuit as devices having a larger memory capacity than magnetic cards. Normally, this IC card is often carried around in a purse or the like, and is thus applied with bending force when being carried around. Conventional IC chips or semiconductor chips formed on a silicon wafer are not flexible themselves and are relatively vulnerable. The IC chips may therefore be broken by external force, like bending force, applied thereto. If such an IC chip is given a flexibility, it can be prevented from being broken. For example, Unexamined Japanese Patent Application KOKAI Publication No. H9-312349 discloses a scheme of transferring a semiconductor IC chip, formed on a silicon wafer, to a flexible resin sheet. The publication describes that a flexible resin sheet is connected to the top of a semiconductor film formed on a silicon wafer to be integrated with the semiconductor film, then the flexible resin sheet can be separated together with the semiconductor film from the silicon wafer.

The technique disclosed in Unexamined Japanese Patent Application KOKAI Publication No. H9-312349 has the following problems. The yield at the step of separating a semiconductor IC chip from a silicon wafer and the step of transferring the semiconductor IC chip to the flexible resin sheet, thus increasing the manufacturing cost. At the time of transferring the semiconductor IC chip formed on the silicon wafer to the flexible resin sheet, the silicon wafer should be cut from the back side to become thinner. Because it is very difficult to make the silicon wafer thinner by etching using an etchant, cutting should be done mechanically by CMP (Chemical Mechanical Polishing) or the like. Therefore, the process becomes a single wafer process and thus takes a longer time. As an IC chip is opaque and has a thickness of several micrometers or so, the range of application is limited.

Unexamined Japanese Patent Application KOKAI Publication No. S62-160292 discloses a method of preparing an IC card by forming a silicon film directly on a plastic substrate to a thickness of 0.5 to 1 μm or so by CVD (Chemical Vapor Deposition) or sputtering, constituting a thin film integrated circuit (IC) using the silicon film, and laminating a plastic sheet on the IC. This technique does not require the step of separating the IC chip and avoids the aforementioned problem. A similar technique is described in Unexamined Japanese Patent Application KOKAI Publication No. 2002-217421. Laser annealing described in, for example, Unexamined Japanese Patent Application KOKAI Publication No. S56-111213 can be used to crystallize an amorphous silicon thin film formed on a plastic substrate by CVD or the like. Unexamined Japanese Patent Application KOKAI Publication No. H7-202147 describes that a semiconductor integrated circuit using a monocrystalline silicon thin film can have a flexibility as an amorphous insulating layer is laminated on top and bottom sides of the semiconductor integrated circuit to a thickness of 100 μm or less.

Japanese Patent No. 2953023 and Japanese Patent No. 3033123 disclose a liquid crystal display apparatus in which a strip display drive glass substrate with polysilicon thin film transistors formed on a heat-resistive glass is adhered to electrode terminal portions laid at the edge portion of a pair of glass substrates facing each other with a liquid crystal in between to connect the substrates. Japanese Patent No. 2953023 and Japanese Patent No. 3033123 describe that as a liquid crystal display apparatus equipped with a display drive circuit can be manufactured by merely connecting a strip glass polysilicon thin film transistor drive circuit board to the edge portion of the display glass substrate, the manufacture is easier as compared with the conventional liquid crystal display apparatus whose display drive circuit is constituted by attaching a plurality of drive circuit elements each comprised of an IC chip to the display glass substrate one by one.

Unexamined Japanese Patent Application KOKAI Publication No. 2001-215528 discloses a liquid crystal display apparatus in which peripheral drive elements, incorporated in a display panel, are connected to a flexible substrate for connection to an external circuit via metals buried in through holes provided in a glass substrate constituting the display panel.

However, the prior art techniques have the following problems. The manufacture method for an IC card described in Unexamined Japanese Patent Application KOKAI Publication No. S62-160292 has a problem such that an integrated circuit should be formed directly on the top surface of the IC card. This requires an exclusive circuit design and process for each purpose of IC cards, leading to an increased manufacturing cost. The semiconductor device described in Unexamined Japanese Patent Application KOKAI Publication No. H7-202147 suffers an insufficient flexibility and an difficulty in adaptation to the purpose of manufacturing a high-density semiconductor device by laminating a plurality of integrated circuit boards. The liquid crystal display apparatuses described in Japanese Patent No. 2953023 and Japanese Patent No. 3033123 have a problem such that a strip drive circuit board is fragile and is likely to be broken when being mounted on the glass substrate. In addition, the drive circuit board has a thickness of 0.5 to 1.0 mm, making it difficult to laminate a plurality of circuit boards at a high density. Further, the glass substrate has a low thermal conductivity, so that the circuit characteristic is likely to be deteriorated by the self-heating of the drive circuit.

### SUMMARY OF THE INVENTION

Accordingly, it is an object of the present invention to provide a low-cost semiconductor device which has various functions and facilitates mixed mounting of a plurality integrated circuits.

It is another object of the present invention to provide a high-density semiconductor device having a lamination of a plurality of flexible integrated circuit boards using the flexibility of the flexible integrated circuit boards.

It is a further object of the present invention to provide a semiconductor device which achieves an excellent heat discharging characteristic by using a flexible substrate having a high thermal conductivity.

A semiconductor device according to the present invention comprises at least one flexible integrated circuit board having a flexible substrate, and an integrated circuit provided on the flexible substrate and having an amorphous semiconductor thin film, or a polycrystalline or a monocrystalline semiconductor thin film crystallized by laser annealing; and a support substrate on which the at least one flexible integrated circuit board is mounted.

Another semiconductor device according to the present invention comprises at least one flexible integrated circuit board having a flexible substrate, and an integrated circuit provided on the flexible substrate and having an amorphous semiconductor thin film, or a polycrystalline or a monocrystalline semiconductor thin film crystallized by laser annealing; at least one first support substrate on which the at least one flexible integrated circuit board is mounted; and a second support substrate on which the at least one support substrate is mounted.

According to the present invention, an integrated circuit is formed on the top surface of a flexible substrate, and a plurality of flexible integrated circuit boards are mounted as a system on a separate support substrate, thereby achieving a low-cost system integrated circuit device which is light and is not easily breakable. Modules with various functions, such as a memory card and a display, can be constructed by combining ICs having various functions. Furthermore, the semiconductor device of the invention can be used as a systematized integrated circuit part at a stage prior to a module stage.

The use of the present invention can realize a high value-added portable electronic device excellent in portability, such as light and high mechanical strength, and a component of such an electronic device.

### BRIEF DESCRIPTION OF THE DRAWINGS

FIG. 1 is a plan view showing a semiconductor device according to a first embodiment of the present invention;

FIG. 2 is a cross-sectional view of a CMOS circuit to be used in the semiconductor device according to the first embodiment of the present invention;

FIGS. 3A to 3F are cross-sectional views showing a manufacture method for the CMOS circuit to be used in the semiconductor device according to the first embodiment of the present invention step by step;

FIG. 4 is a plan view showing a first modification of the semiconductor device according to the first embodiment of the present invention;

FIG. 5A is a plan view and FIGS. 5B and 5C are cross-sectional views showing a second modification of the semiconductor device according to the first embodiment of the present invention;

FIG. 6 is a plan view showing a semiconductor device according to a second embodiment of the present invention;

FIG. 7 is a plan view showing a first modification of the semiconductor device according to the second embodiment of the present invention;

FIGS. 8A and 8D are plan views and FIGS. 8B and 8C are cross-sectional views showing a second modification and a third modification of the semiconductor device according to the second embodiment of the present invention;

FIG. 9 is a plan view showing a semiconductor device according to a third embodiment of the present invention;

FIG. 10 is a plan view showing a first modification of the semiconductor device according to the third embodiment of the present invention;

FIG. 11A is a plan view and FIG. 11B is a cross-sectional view showing a second modification of the semiconductor device according to the third embodiment of the present invention;

FIG. 12 is a cross-sectional view showing a third modification of the semiconductor device according to the third embodiment of the present invention;

FIG. 13 is a cross-sectional view showing a fourth modification of the semiconductor device according to the third embodiment of the present invention;

FIG. 14 is a cross-sectional view showing a fifth modification of the semiconductor device according to the third embodiment of the present invention;

FIG. 15 is a plan view showing a semiconductor device according to a fourth embodiment of the present invention;

FIG. 16 is a plan view showing a first modification of the semiconductor device according to the fourth embodiment of the present invention;

FIG. 17A is a plan view and FIG. 17B is a cross-sectional view showing a second modification of the semiconductor device according to the fourth embodiment of the present invention;

FIG. 18 is a cross-sectional view showing a semiconductor device according to a fifth embodiment of the present invention;

FIG. 19 is a cross-sectional view showing a first modification of the semiconductor device according to the fifth embodiment of the present invention;

FIG. 20 is a cross-sectional view showing a second modification of the semiconductor device according to the fifth embodiment of the present invention;

FIG. 21 is a cross-sectional view showing a semiconductor device according to a sixth embodiment of the present invention;

FIG. 22 is a cross-sectional view showing a first modification of the semiconductor device according to the sixth embodiment of the present invention; and

FIG. 23 is a cross-sectional view showing a second modification of the semiconductor device according to the sixth embodiment of the present invention.

### DETAILED DESCRIPTION OF THE PREFERRED EMBODIMENTS

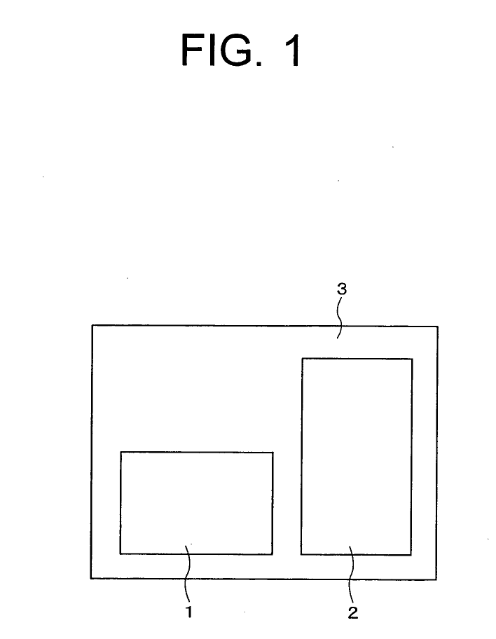

Preferred embodiments of the present invention will be described specifically below with reference to the accompanying drawings. To begin with, the first embodiment of the present invention will be described. FIG. 1 is a plan view showing a semiconductor device according to the embodiment. As shown in FIG. 1, the semiconductor device of the embodiment is provided with a support substrate 3 on whose top surface flexible integrated circuit boards 1 and 2 are mounted. A plastic substrate, for example, is used for the support substrate 3. CMOS (Complementary Metal Oxide Semiconductor) integrated circuits formed by polycrystalline semiconductor TFTs (Thin Film Transistors) are formed on the top surfaces of the flexible integrated circuit boards 1 and 2

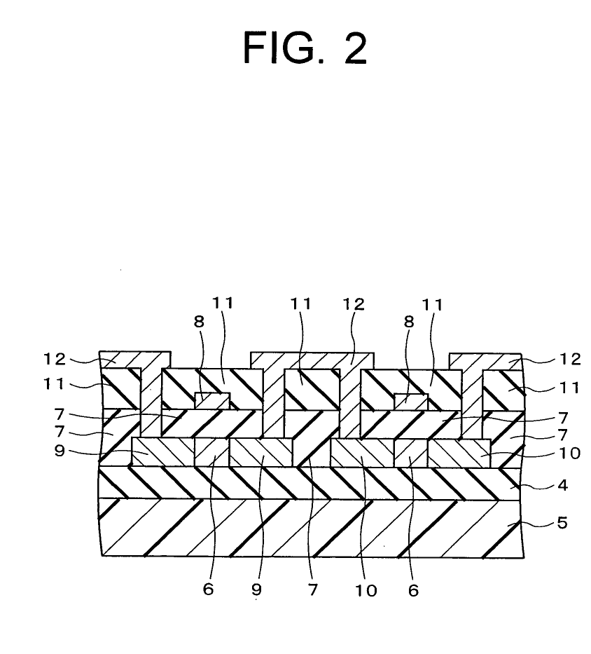

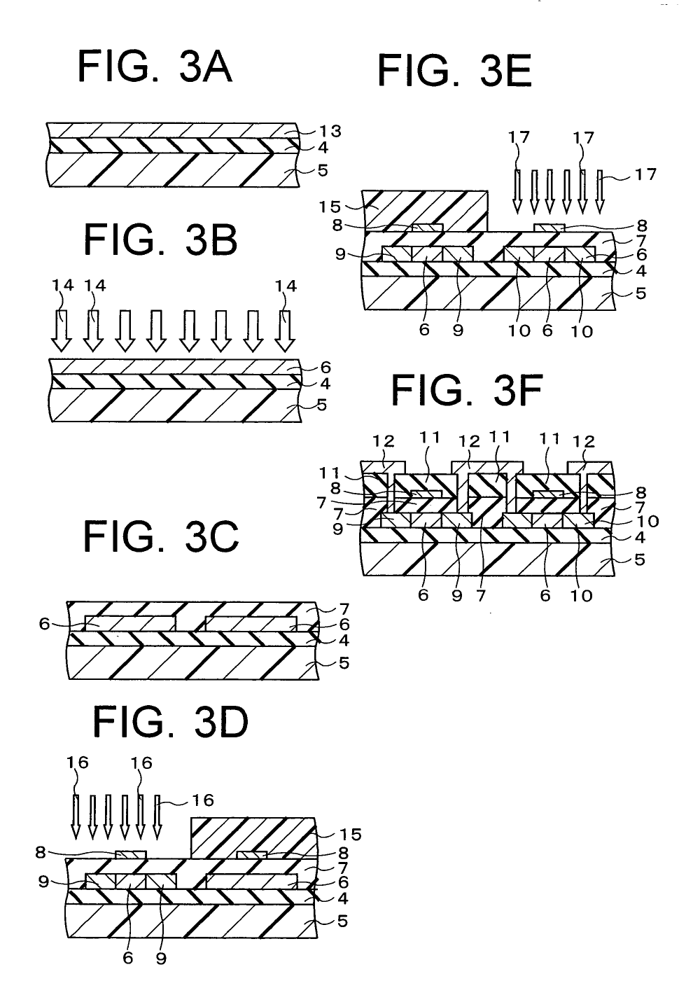

FIG. 2 is a cross-sectional view showing the basic structure of the CMOS circuit, and FIGS. 3A to 3F are cross-sectional views showing a manufacture method for the TFT step by step. As shown in FIG. 2, a TFT which is used in the semiconductor device of the embodiment is provided with a flexible substrate 5 on which a barrier film 4 is formed, and two polycrystalline silicon films 6 are formed on the barrier film 4. A resin substrate, such as a polyimide film, for example, is used for the flexible substrate 5. The barrier film 4 serves to suppress diffusion of an impurity, such as water and an organic substance, to the TFT from the resin substrate and prevent degrading of the characteristic of the TFT. A metal oxide film of, for example, silicon oxide, aluminum oxide or tantalum oxide, is used for the barrier film 4. A metal nitride, such as silicon nitride, may be used instead of the oxide film. A p-type region 9 is provided on either end portion of one of the two polycrystalline silicon films 6, and an n-type region 10 is provided on either end portion of one of the other polycrystalline silicon film 6. A gate insulating film 7 is formed in such a way as to cover the polycrystalline silicon films 6 and the barrier film 4, and a gate electrode 8 is formed on the top surface of the gate insulating film 7. An interlayer insulating film 11 is formed in such a way as to cover the gate electrode 8 and the gate insulating film 7, and a metal electrode 12 is formed on the top surface of the interlayer insulating film 11. The metal electrode 12 penetrates the interlayer insulating film 11 and the gate insulating film 7 to be connected to the p-type regions 9 and the n-type regions 10, both provided at the polycrystalline silicon films 6.

In the manufacturing process for the TFT, as shown in FIG. 3A, the barrier film 4 is formed on the top surface of the flexible substrate 5 by, for example, sputtering, and an amorphous silicon film 13 is formed on the top surface of the barrier film 4. The amorphous silicon film 13 is formed 30 to 200 nm thick by, for example, CVD (Chemical Vapor Deposition) or sputtering. Next, as shown in FIG. 3B, the amorphous silicon film 13 is annealed by laser irradiation 14 to be reformed into the polycrystalline silicon film 6. An excimer laser or a solid-state laser or the like, for example, is used as the laser. Next, the polycrystalline silicon film 6 on the barrier film 4 is patterned by the photolithography technology, after which the gate insulating film 7 is formed in such a way as to cover the barrier film 4 and the two polycrystalline silicon films 6, as shown in FIG. 3C. The gate insulating film 7 is formed 10 to 200 nm thick by, for example, CVD or sputtering. After the formation of the gate insulating film 7, laser irradiation onto the entire surface with an energy density lower than that of the laser irradiation 14 in order to reduce the amount of fixed charges present at the interface between the polycrystalline silicon and the gate insulating film 7, and the interface level. Next, as shown in FIG. 3D, two gate electrodes 8 are formed on the top surface of the gate insulating film 7 at positions facing the two polycrystalline silicon films 6. Further, a resist 15 is formed at a position facing one of the polycrystalline silicon films 6 in such a way as to cover the gate electrode 8 and the interlayer insulating film 7, and boron is injected from the top surface of the interlayer insulating film 7, thereby forming the p-type regions 9 on both end portions of the other polycrystalline silicon film 6. The boron injection is carried out by, for example, ion doping. With the resist 15 serving as a mask, boron is not injected into one polycrystalline silicon film 6. With the gate electrode 8 being a mask, boron is not injected into the center portion of the other polycrystalline silicon film 6. Next, as shown in FIG. 3E, the resist 15 is formed at that position facing the polycrystalline silicon film 6 where the p-type regions 9 are not provided, in such a way as to cover the gate electrode 8 and the interlayer insulating film 7. The n-type regions 10 are formed on both end portions of the other polycrystalline silicon film 6 by injection of phosphorus from the top surface of the interlayer insulating film 7. The phosphorus injection is carried out by, for example, ion doping. With the resist 15 serving as a mask, phosphorus is not injected into one polycrystalline silicon film 6. With the gate electrode 8 serving as a mask, phosphorus is not injected into the center portion of the other polycrystalline silicon film 6. Next, as shown in FIG. 3F, the interlayer insulating films 11 and the metal electrodes 12 are formed to complete a CMOS circuit. In the entire process in manufacturing the CMOS circuit, the desirable process temperature at the deposition step by CVD or sputtering or the like is 450° C. in consideration of the heat resistance of the plastic or resin substrate or the like.

In the semiconductor device according to the embodiment, a flexible integrated circuit board is mounted on the support substrate, so that the semiconductor device is not easily broken when external force, such as bending force, is applied to the entire semiconductor device. Although two flexible integrated circuit boards are mounted on the support substrate 3 in the embodiment, the invention is not limited to the embodiment and a single flexible integrated circuit board or a plurality of flexible integrated circuit boards may be mounted. For example, a memory circuit which stores data, a control circuit which sends signals to external devices or the like and controls the their operations, a display device which has a pixel circuit or the like and displays an image, a sensor device which has a light receiving element or the like to detect light, and a CCD (Charge-Coupled Device) to be used in a digital camera or the like are used as integrated circuits provided on the flexible integrated circuit boards. Although a polycrystalline thin film semiconductor crystallized by laser annealing is used for an integrated circuit to be formed on the top surface of the flexible substrate, a monocrystalline thin film semiconductor crystallized by laser annealing may be used or an amorphous thin film semiconductor may be used instead.

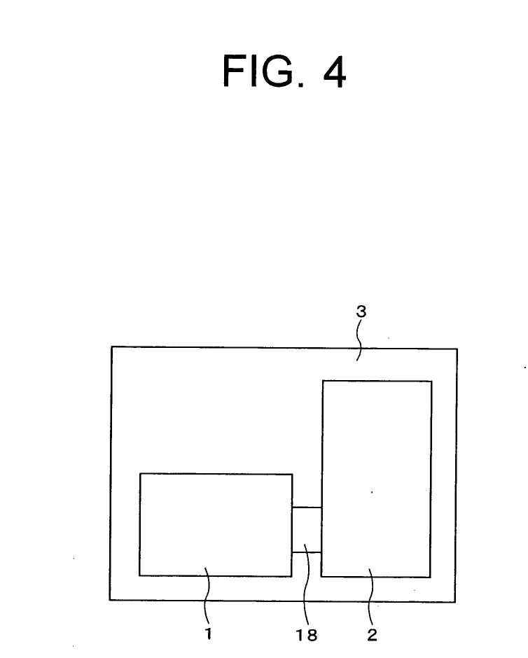

FIG. 4 is a plan view showing a first modification of the semiconductor device according to the first embodiment of the invention. As shown in FIG. 4, the flexible integrated circuit boards 1 and 2 provided on the top surface of the support substrate 3 are electrically connected by an electric connecting portion 18, thereby constituting a system integrated circuit device. The electric connection may be made by overlaying the terminal portions (not shown) of the flexible integrated circuit boards 1 and 2 and then connecting them by a conductive resin.

In the first modification of the semiconductor device according to the first embodiment with the above-described structure, as shown in FIG. 2, the flexible integrated circuit boards 1 and 2 provided on the support substrate are connected to each other via the electric connecting portion 18 and can function as a single integrated system. The other effects of the first modification of the semiconductor device according to the first embodiment are the same as those of the first embodiment.

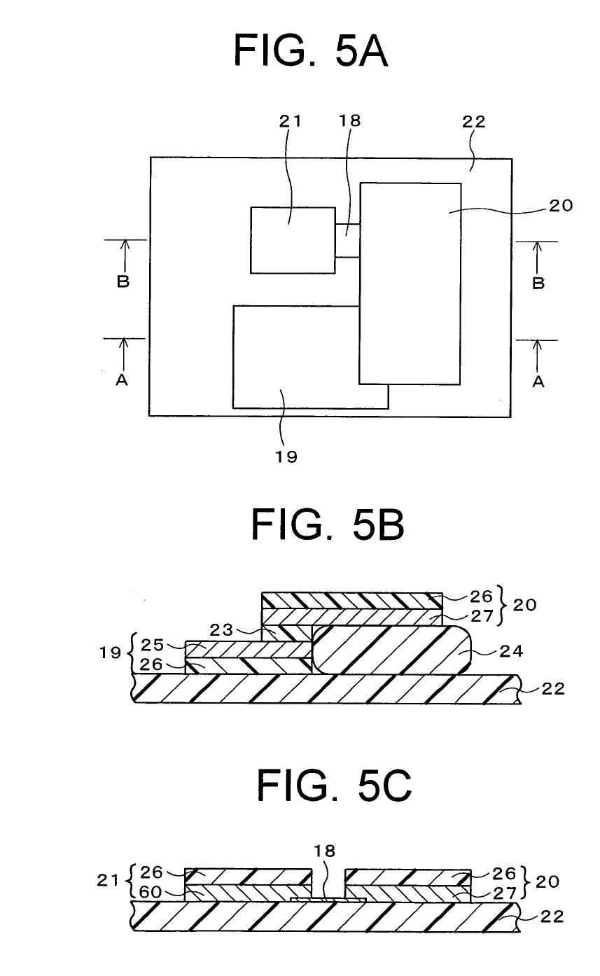

FIG. 5A is a plan view showing a second modification of the semiconductor device according to the first embodiment, FIG. 5B is a cross-sectional view along line A-A shown in FIG. 5A, and FIG. 5C is a cross-sectional view along line B-B shown in FIG. 5A. As shown in FIGS. 5A and 5B, a plastic card 22 is provided and a flexible memory circuit board 19 is mounted on the top surface of the plastic card 22. The flexible memory circuit board 19 is provided with a flexible substrate 26 on whose top surface a memory circuit 25 is provided. A polyimide film, for example, is used for the flexible substrate 26. The flexible memory circuit board 19 is mounted in such a way that the side lying on that side of the flexible substrate 5 contacts the plastic card 22. An adhesive layer 24 is provided on the top surface of the plastic card 22, and a flexible control circuit board 20 is mounted on the adhesive layer 24. The flexible memory circuit board 20 is provided with a flexible substrate 26 on whose top surface a control circuit 27 is provided. The flexible memory circuit board 20 is mounted in such a way that the side lying on that side of the control circuit 27 contacts the adhesive layer 24. The flexible memory circuit board 19 and the flexible control circuit board 20 are mounted in such a way that their terminal portions (not shown) overlie each other, and the memory circuit 25 and the control circuit 27 are connected together by a conductive resin 23. The memory circuit 25 and the control circuit 27 are each provided with a connecting terminal portion (not shown) and a metal bump (not shown), and their electric connection can be achieved by crimping both with the conductive resin in between. As shown in FIGS. 5A and 5C, the electric connecting portion 18 is provided on the top surface of the plastic card 22, and the flexible control circuit board 20 and a flexible power supply circuit board 21 are also mounted on the plastic card 22. The flexible power supply circuit board 21 is provided with a flexible substrate 26 on whose top surface a power supply circuit 60 is provided. The flexible control circuit board 20 is mounted in such a way that the side lying on that side of the control circuit 27 contacts the plastic card 22, while the flexible power supply circuit board 21 is mounted in such a way that the side lying on that side of the power supply circuit 60 contacts the plastic card 22. The control circuit 27 and the power supply circuit 60 are mounted in such a way that their end portions overlie the electric connecting portion 18.

According to the second modification of the semiconductor device according to the embodiment with the above-described structure, as shown in FIGS. 5A, 5B and 5C, the flexible memory circuit board 19 and the flexible control circuit board 20 can be mounted on the plastic card 22 in such a way as to partly overlie each other. The use of a flexible integrated circuit board can achieve a high-density and multifunction semiconductor device at a high reliability. Examples of a semiconductor device with such a structure are an IC card and an IC tag. The IC card may be a credit card. The IC tag is a small tag (price tag) which is adhered to a commodity and is read by radio wave. Those semiconductor devices are often carried around and are likely to be applied with external force, such as bending force, but the use of a flexible circuit board makes the semiconductor devices harder to break.

According to the first embodiment, as apparent from the above, a system integrated circuit device which is light and is not easily breakable can be manufactured at a low cost by mounting a plurality of flexible integrated circuit boards as a system on the support substrate 3. Modules with various functions, such as a memory card and a display, can be constructed by combining ICs having various functions.

Although a conductive resin is used as the electric connecting portion 18 in the first embodiment, the mating terminal portions may be connected by metal wires. Although a polycrystalline semiconductor thin film crystallized by laser annealing is used as a semiconductor thin film to be used in a CMOS-TFT which constitutes a flexible integrated circuit, an amorphous semiconductor thin film or a monocrystalline semiconductor thin film crystallized by laser annealing may be used instead. Although a polyimide film is used as the flexible substrate 26, another synthetic resin film, such as a PET (Poly-Ethylene Terephthalate) film, a metal film, or a lamination of both types of films may be used, a natural resin film formed by molding rosin or the like may be used as well While a plastic substrate is used as the support substrate 3, a glass substrate, a metal substrate, a synthetic resin substrate, a natural resin substrate, or a lamination of those substrates may also be used.

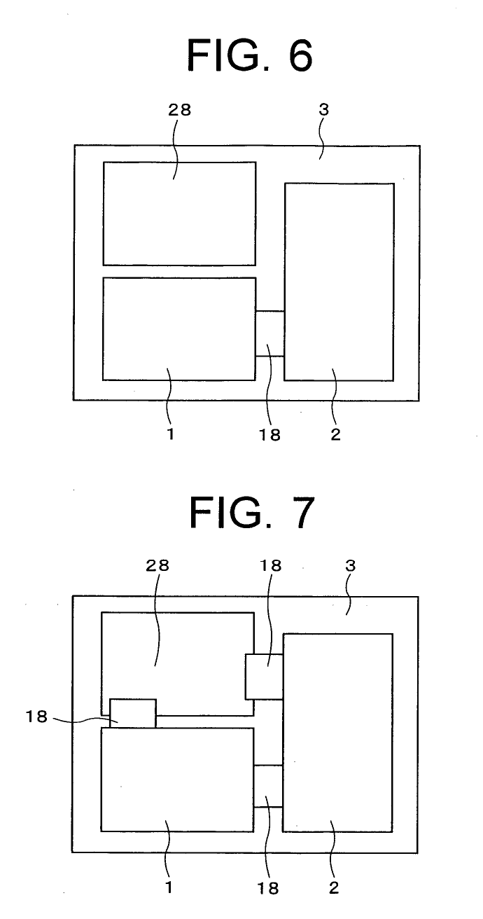

The second embodiment of the invention will now be described. FIG. 6 is a plan view showing a semiconductor device according to the second embodiment. In the first modification of the first embodiment, as shown in FIG. 2, no integrated circuit is provided on the support substrate 3. According to the second embodiment, however, an integrated circuit 28 directly fabricated on a support substrate beforehand is provided on the support substrate 3, as shown in FIG. 6. A high heat-resistance material like a silicon wafer is used as the support substrate 3. The other structure of the second embodiment shown in FIG. 6 is the same as that of the first embodiment shown in FIG. 2.

In the semiconductor device according to the second embodiment with the above-described structure, a thin film semiconductor having a very high performance can be formed on the top surface of the support substrate 3 by using a high heat-resistance material, such as a silicon wafer, as the support substrate 3. It is therefore possible to manufacture a multi-function semiconductor device in which a circuit requiring a very high transistor characteristic, such as a microprocessor, is formed on a silicon wafer and a flexible integrated circuit board is provided there. When a plastic substrate, for example, is used as a support substrate, an amorphous semiconductor thin film, or a polycrystalline or monocrystalline semiconductor thin film crystallized by laser annealing is used. The other effects of the second embodiment are the same as those of the first modification of the first embodiment as shown in FIG. 2.

FIG. 7 is a plan view showing a first modification of the semiconductor device according to the second embodiment of the invention. In the second embodiment, as shown in FIG. 6, the flexible integrated circuits 1 and 2 are not electrically connected to the integrated circuit 28 directly formed on the support substrate. According to the first modification of the second embodiment, by way of contrast, the flexible integrated circuits 1 and 2 are electrically connected to the integrated circuit 28 directly formed on the support substrate by the respective electric connecting portions 18 provided on the top surface of the support substrate 3, as shown in FIG. 7.

In the first modification of the semiconductor device according to the second embodiment with the above-described structure, the flexible integrated circuits 1 and 2 are electrically connected to the integrated circuit 28 directly formed on the support substrate by the respective electric connecting portions 18 provided on the top surface of the support substrate 3, they can function as a single integrated system. The other effects of the first modification of the second embodiment are the same as those of the second embodiment shown in FIG. 6.

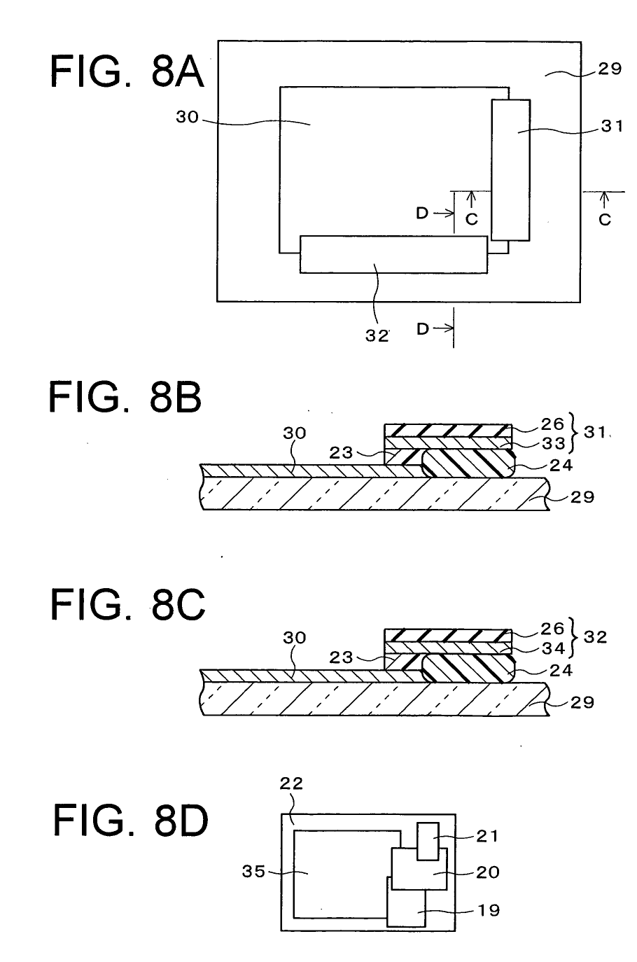

FIG. 8A is a plan view showing a second modification of the semiconductor device according to the second embodiment, FIG. 8B is a cross-sectional view along line C-C in FIG. 8A, and FIG. 8C is a cross-sectional view along line D-D in FIG. 8A. As shown in FIGS. 8A and 8B, a glass substrate 29 is provided and a pixel circuit 30 is formed on the top surface of the glass substrate 29 beforehand. The pixel circuit 30 is used in, for example, a display module, such as a liquid crystal display panel. The pixel circuit 30 has pixel electrodes (not shown) laid out in a matrix form, and a plurality of scan lines which transfer a scan pulse to the pixel electrodes and a plurality of data lines which transfer a video signal to the pixel electrodes are formed in such a way as to cross each other. An adhesive layer 24 is provided on the top surface of the glass substrate 29, and a flexible scan line drive circuit board 31 which outputs the scan pulse to the scan lines is mounted on the adhesive layer 24. The flexible scan line drive circuit board 31 is provided with the flexible substrate 26 on whose top surface a scan line drive circuit 33 is provided. A polyimide film, for example, is used as the flexible substrate 26. The flexible scan line drive circuit board 31 is mounted in such a way that the side lying on that side of the scan line drive circuit 33 contacts the adhesive layer 24. The flexible scan line drive circuit board 31 and the pixel circuit 30 are mounted in such a way that their terminal portions (not shown) overlie each other, and the scan line drive circuit 33 and the pixel circuit 30 are connected by the conductive resin 23. The pitch of the terminal portions of the scan line drive circuit 33 is provided in such a way as to match with the pitch of the terminal portions formed at the edge portion of the pixel circuit 30. Metal bumps (not shown) are formed at the terminal portions of the scan line drive circuit 33 by plating or the like, and are electrically connected to the terminal portions of the pixel circuit 30 by crimping via a conductive resin 23, such as an anisotropic conductive film. As shown in FIGS. 8A and 8C, the glass substrate 29 is provided and the pixel circuit 30 is formed on the top surface of the glass substrate 29 beforehand. The adhesive layer 24 is provided on the top surface of the glass substrate 29, and a flexible data line drive circuit board 32 which outputs a video signal to the data lines is mounted on the adhesive layer 24. The flexible data line drive circuit board 32 is provided with the flexible substrate 26 on whose top surface a data line drive circuit 34 is provided. The flexible data line drive circuit board 32 is mounted in such a way that the side lying on that side of the data line drive circuit 34 contacts the adhesive layer 24. The flexible data line drive circuit board 32 and the pixel circuit 30 are mounted in such a way that their terminal portions (not shown) overlie each other, and the data line drive circuit 34 and the pixel circuit 30 are connected by the conductive resin 23. The pitch of the terminal portions of the data line drive circuit 34 is provided in such a way as to match with the pitch of the terminal portions formed at the edge portion of the pixel circuit 30. Metal bumps (not shown) are formed at the terminal portions of the data line drive circuit 34 by plating or the like, and are electrically connected to the terminal portions of the pixel circuit 30 by crimping via the conductive resin 23, such as an anisotropic conductive film.

In the second modification of the semiconductor device according to the second embodiment with the above-described structure, as shown in FIGS. 8A, 8B and 8C, flexible circuit boards are used as the scan line drive circuit board and the data line drive circuit board, so that when the semiconductor device becomes elongated, particularly, a display module can be manufactured with a high yield without being cracked at the time of crimping. The drive circuit that is constituted on the flexible substrate may include the functions of a digital/analog conversion circuit and a memory circuit.

FIG. 8D is a plan view showing a third modification of the embodiment. As shown in FIG. 8D, a plastic card 22 is provided, and an antenna circuit 35 which transmits and receives signals to and from an external device is provided at the top surface of the plastic card 22. The flexible memory circuit board 19 is mounted on the top surface of the plastic card 22 in such a way that the end portions overlie the antenna circuit 35. Information, such as the account number of a bank, is stored in the flexible memory circuit board 19. The flexible control circuit board 20 is mounted on the top surface of the plastic card 22 in such a way that the end portions overlie the antenna circuit 35 and the flexible memory circuit board 19. The flexible control circuit board 20 performs arithmetic operations to, for example, encrypt the account number of the bank. Further, the flexible power supply circuit board 21 is mounted on the top surface of the plastic card 22 in such a way that the end portions overlie the flexible control circuit board 20. The flexible power supply circuit board 21 supplies the flexible control circuit board 20 with power to drive the control circuit. The thus constructed semiconductor device is used as, for example, a credit card.

In the third modification of the semiconductor device according to the second embodiment with the above-described structure, the flexible memory circuit board 19, the flexible control circuit board 20 and the flexible power supply circuit board 21, all of which have a flexibility, are used as the memory circuit board, the control circuit board and the power supply circuit board. This brings about an effect such that so that when external force is applied to the entire semiconductor device, the semiconductor device is hard to break. A microprocessor circuit or the like which performs, for example, encryption on data may be added to the basic structure. A plurality of integrated circuits may be provided on the support substrate before hand.

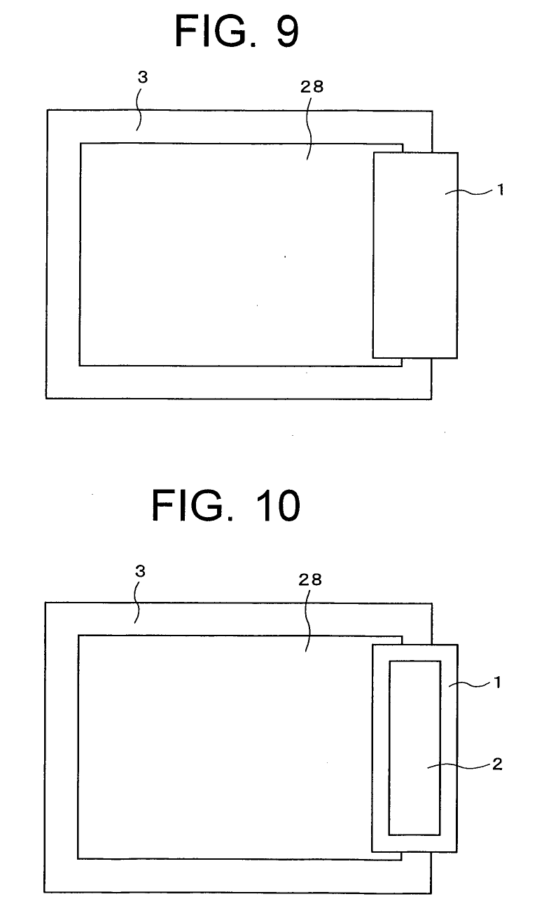

The third embodiment of the invention will now be described. FIG. 9 is a plan view showing a semiconductor device according to the third embodiment. As shown in FIG. 9, the semiconductor device of the embodiment is provided with the support substrate 3 on whose top surface an integrated circuit formed directly on a support substrate beforehand is provided. The flexible integrated circuit board 1 is mounted on the support substrate 3 in such a way as to partly extend out of the top surface of the support substrate 3.

In the semiconductor device according to the third embodiment with the above-described structure, as shown in FIG. 9, the flexible integrated circuit board 1 mounted on the support substrate 3 has a flexibility, so that if the flexible integrated circuit board 1 is mounted so as to extend from the top surface of the support substrate 3, a highly reliable semiconductor device can be realized.

FIG. 10 is a plan view showing a first modification of the semiconductor device according to the third embodiment. In the first modification of the third embodiment, as shown in FIG. 10, the flexible integrated circuit board 2 is further mounted on the flexible integrated circuit board 1 in the semiconductor device in FIG. 9.

According to the first modification of the semiconductor device according to the third embodiment with the above-described structure, when an integrated circuit board is further mounted on the semiconductor device of the third embodiment shown in FIG. 9, the flexible integrated circuit board 2 can be mounted on the flexible integrated circuit board 1 without widening the area of the support substrate 3. The use of the flexible integrated circuit board increases the degree of freedom of the mounting mode of the semiconductor device.

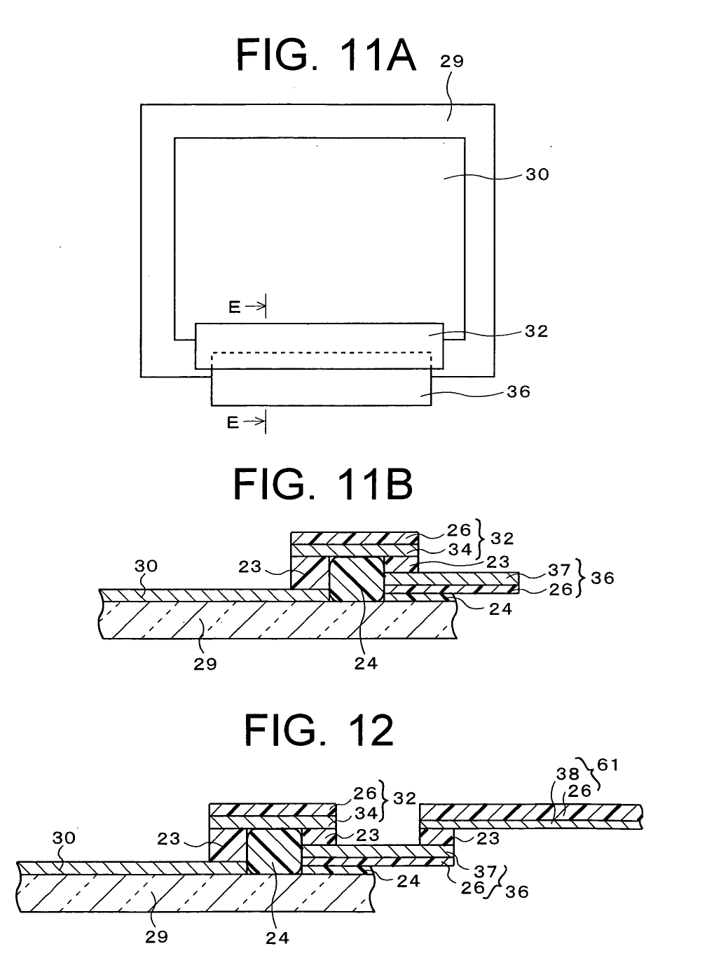

FIG. 11A is a plan view showing a second modification of the semiconductor device according to the second embodiment, FIG. 11B is a cross-sectional view along line E-E in FIG. 11A. As shown in FIGS. 11A and 11B, the glass substrate 29 is provided and the pixel circuit 30 is formed on the top surface of the glass substrate 29 beforehand. The pixel circuit 30 is used in, for example, a display module, such as a liquid crystal display panel. The pixel circuit 30 has pixel electrodes (not shown) laid out in a matrix form, and a plurality of data lines which transfer a video signal to the pixel electrodes are formed. The adhesive layer 24 is provided at the end portion of the top surface of the glass substrate 29, and a flexible memory circuit board 36 is mounted on the adhesive layer 24 in such a way as to partly extend out from the top surface of the glass substrate 29. The flexible memory circuit board 36 and the pixel circuit 30 do not overlie each other. The flexible memory circuit board 36 is provided with the flexible substrate 26 on whose top surface a memory circuit 37 is provided. The flexible memory circuit board 36 is mounted in such a way that the side lying on that side of the flexible substrate 26 contacts the adhesive layer 24. The adhesive layer 24 is provided on the top surface of the glass substrate 29 at a region between the pixel circuit 30 and the flexible memory circuit board 36. The flexible data line drive circuit board 32 is mounted on the adhesive layer 24. The flexible data line drive circuit board 32 is provided with the flexible substrate 26 on whose top surface a data line drive circuit 34 is provided. The flexible data line drive circuit board 32 is mounted in such a way that the side lying on that side of the data line drive circuit 34 contacts the adhesive layer 24. The flexible data line drive circuit board 32 and the pixel circuit 30 are mounted in such a way that their terminal portions (not shown) overlie each other, and the data line drive circuit 34 and the pixel circuit 30 are connected by the conductive resin 23. The pitch of the terminal portions of the data line drive circuit 34 is provided in such a way as to match with the pitch of the terminal portions formed at the edge portion of the pixel circuit 30. Metal bumps (not shown) are formed at the terminal portions of the data line drive circuit 34, and are electrically connected to the terminal portions of the pixel circuit 30 via the conductive resin 23. The flexible data line drive circuit board 32 and the flexible memory circuit board 36 are mounted in such a way that their terminal portions (not shown) overlie each other, and the data line drive circuit 34 and the memory circuit 37 are connected by the conductive resin 23. The pitch of the terminal portions of the data line drive circuit 34 is provided in such a way as to match with the pitch of the terminal portions formed at the edge portion of the memory circuit 37. Metal bumps (not shown) are formed at the terminal portions of the data line drive circuit 34, and are electrically connected to the terminal portions of the memory circuit 37 via the conductive resin 23.

In the second modification of the semiconductor device according to the third embodiment with the above-described structure, as shown in FIGS. 11A and 11B, because the flexible memory circuit board 36 and the flexible data line drive circuit board 32 have a flexibility, it is possible to take the mounting mode of the second modification of the semiconductor device according to the third embodiment. In particular, it is unnecessary to mount the entire integrated circuit board on a support substrate, resulting in less restriction on the mounting space. Accordingly, high density mounting can be realized reliably and a display module can be designed compact. Although the embodiment is illustrated as a display module, the invention is not restrictive to the type, flexible integrated circuit boards having various functions can be arbitrarily laminated one on another and connected together, and the laminated flexible integrated circuit boards can be mounted at any place on the support substrate with a high yield.

FIG. 12 is a cross-sectional view showing a third modification of the semiconductor device according to the third embodiment. As shown in FIG. 12, a flexible wiring board 61 is connected to the flexible memory circuit board 36 of the semiconductor device in FIG. 11B. The flexible wiring board 61 is provided with the flexible substrate 26 on whose top surface a copper wiring 38 is provided. The flexible memory circuit board 36 and the flexible wiring board 61 are mounted in such a way that their terminal portions (not shown) overlie each other, and the memory circuit 37 and the copper wiring 38 is connected together by the conductive resin 23.

In the third modification of the semiconductor device according to the third embodiment with the above-described structure, as the flexible memory circuit board 36 and the flexible wiring board 61 have a flexibility, the flexible memory circuit board 36 and the flexible wiring board 61 can be connected to each other at the portion extending out of the top surface of the glass substrate 29. Accordingly, the terminal portions for connecting the flexible memory circuit board 36 to the flexible wiring board 61 and wirings for connecting the terminal portions need not be provided at the top surface of the glass substrate 29. This can achieve high-density mounting with a high reliability, and can design a display module compact. The other effects of the third modification of the third embodiment are the same as those of the second modification of the third embodiment.

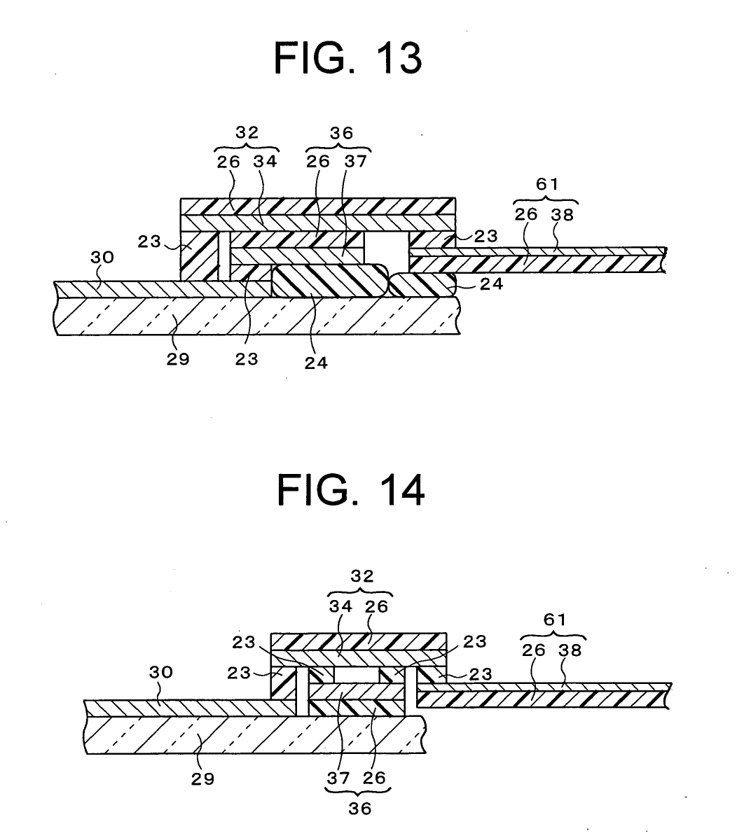

FIG. 13 is a cross-sectional view showing a fourth modification of the semiconductor device according to the third embodiment. As shown in FIG. 13, the pixel circuit 30 is provided at the top surface of the glass substrate 29 beforehand. The adhesive layer 24 is provided at the top surface of the end portion of the glass substrate 29, and the flexible wiring board 61 having the copper wiring 38 provided on the top surface of the flexible substrate 26 is mounted on the adhesive layer 24 in such a way that the end portion of the side lying on that side of the flexible substrate 26 contacts the adhesive layer 24. The flexible data line drive circuit board 32 having the data line drive circuit 34 provided on the top surface of the flexible substrate 26, and the flexible memory circuit board 36 having the memory circuit 37 provided on the top surface of the flexible substrate 26 are laminated one on the other. The lamination is made in such a way that the data line drive circuit 34 side of the flexible data line drive circuit board 32 is adhered to the flexible substrate 26 side of the flexible memory circuit board 36. A thermosetting or photocuring adhesive is used for the adhesion. The laminated body is mounted on the glass substrate 29 via the adhesive layer 24 in such a way that the memory circuit 37 contacts the adhesive layer 24. Each pair of the pixel circuit 30 and the data line drive circuit 34, the pixel circuit 30 and the memory circuit 37, and the data line drive circuit 34 and the copper wiring 38 are connected together by the conductive resin 23.

In the fourth modification of the semiconductor device according to the third embodiment with the above-described structure, the flexible data line drive circuit board 32 and the flexible wiring board 61 are connected together. The fourth modification differs from the third modification of the third embodiment in this point, but is identical to the third modification in the other structure and functions. The fourth modification can apparently realize a semiconductor device having functions similar to those of the third modification in various mounting modes, and has a higher degree of freedom in mounting structure. The other effects of the fourth modification are the same as those of the third modification of the third embodiment.

FIG. 14 is a cross-sectional view showing a fifth modification of the semiconductor device according to the third embodiment. As shown in FIG. 14, the pixel circuit 30 is provided at the top surface of the glass substrate 29 beforehand. The flexible data line drive circuit board 32 having the data line drive circuit 34 provided on the top surface of the flexible substrate 26, and the flexible memory circuit board 36 having the memory circuit 37 provided on the top surface of the flexible substrate 26 are laminated one on the other. The lamination is made in such a way that the terminal portions (not shown) of the data line drive circuit 34 side of the flexible data line drive circuit board 32 and the memory circuit 37 side of the flexible memory circuit board 36 are connected together by the conductive resin 23. The laminated body is mounted on the glass substrate 29 via the adhesive layer 24 in such a way that the flexible substrate 26 side of the flexible memory circuit board 36 contacts the top surface of the glass substrate 29. The pixel circuit 30 and the data line drive circuit 34 are connected together by the conductive resin 23. The flexible wiring board 61 having the copper wiring 38 provided on the top surface of the flexible substrate 26 is connected, at the copper wiring 38, to the data line drive circuit 34 by the conductive resin 23 to be thereby connected to the flexible data line drive circuit board 32.

In the thus constructed fifth modification of the semiconductor device according to the third embodiment, the flexible memory circuit board 36 and the flexible data line drive circuit board 32 are electrically connected together by the conductive resin 23. The fifth modification differs from the third modification of the third embodiment in this point, but is identical to the third modification in the other structure and functions. The fourth modification can apparently realize a semiconductor device having functions similar to those of the third modification in various mounting modes, and has a higher degree of freedom in mounting structure. The other effects of the fourth modification are the same as those of the third modification of the third embodiment.

The fourth embodiment of the invention will now be described. FIG. 15 is a plan view showing a semiconductor device according to the fourth embodiment. As shown in FIG. 15, the semiconductor device of the embodiment is provided with a support substrate 39 on whose top surface integrated circuits 46 and 47 formed directly on a support substrate beforehand are provided. The integrated circuits 46 and 47 are connected together by the electric connecting portion 18. A support substrate 40 is provided, and flexible integrated circuit boards 42 and 43 are mounted on the top surface of the support substrate 40. The flexible integrated circuit board 43 is mounted in such a way as to partly overlie the flexible integrated circuit board 42. A support substrate 41 is provided, and flexible integrated circuit boards 44 and 45 are mounted on the top surface of the support substrate 41. The flexible integrated circuit board 45 is mounted in such a way as to partly overlie the flexible integrated circuit board 44. The support substrates 40 and 41 are mounted on the top surface of the support substrate 39. The integrated circuit 46 formed directly on the support substrate and provided on the support substrate 39 is connected to the flexible integrated circuit board 43 mounted on the support substrate 40 by the electric connecting portion 18. The integrated circuit 47 formed directly on the support substrate and provided on the support substrate 39 is connected to the flexible integrated circuit board 45 mounted on the support substrate 41 by the electric connecting portion 18.

In the semiconductor device according to the fourth embodiment with the above-described structure, as shown in FIG. 15, the flexible integrated circuit boards 42 and 43 mounted on the support substrate 40, the flexible integrated circuit boards 44 and 45 mounted on the support substrate 41, and the integrated circuits 47 and 48 directly formed on the support substrate can function as a single integrated system, thereby achieving a high-performance semiconductor device having a higher added value. The other effects of the fourth embodiment are the same as those of the second embodiment shown in FIG. 6.

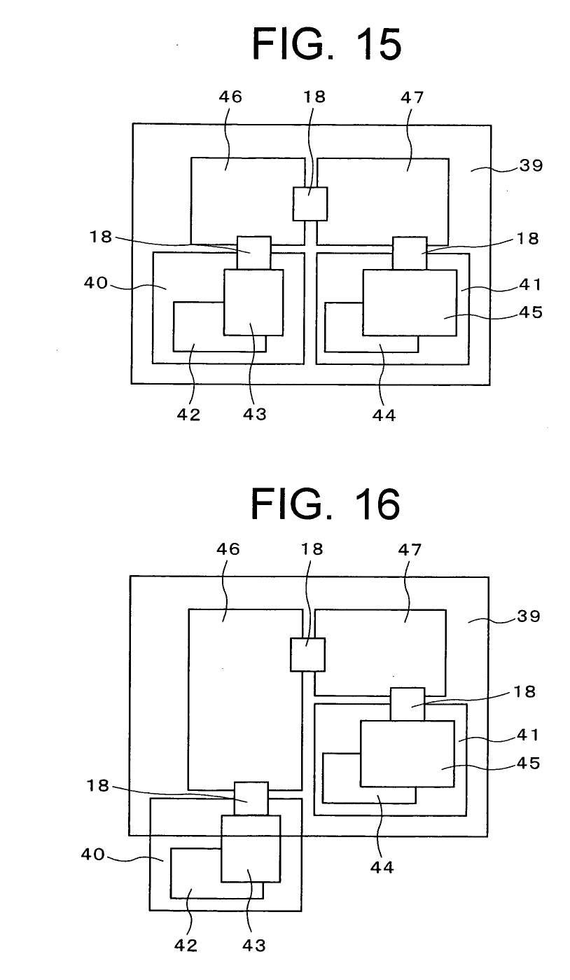

FIG. 16 is a plan view showing a first modification of the semiconductor device according to the fourth embodiment. In the first modification of the fourth embodiment, as shown in FIG. 16, when the area of the integrated circuit 46 directly formed on the support substrate provided o the support substrate 39 in the semiconductor device in FIG. 15 is increased, the support substrate 40 on which the flexible integrated circuit boards 42 and 43 are mounted is mounted on the support substrate 39 in such a way as to partly extend out of the top surface of the support substrate 39.

In the thus constructed semiconductor device according to the fourth embodiment, as shown in FIG. 16, the support substrate 40 can be mounted in such a way as to extend out of another support substrate 39, thereby further increasing the degree of freedom of mounting. The other effects of the first modification of the fourth embodiment are the same as those of the fourth embodiment shown in FIG. 15.

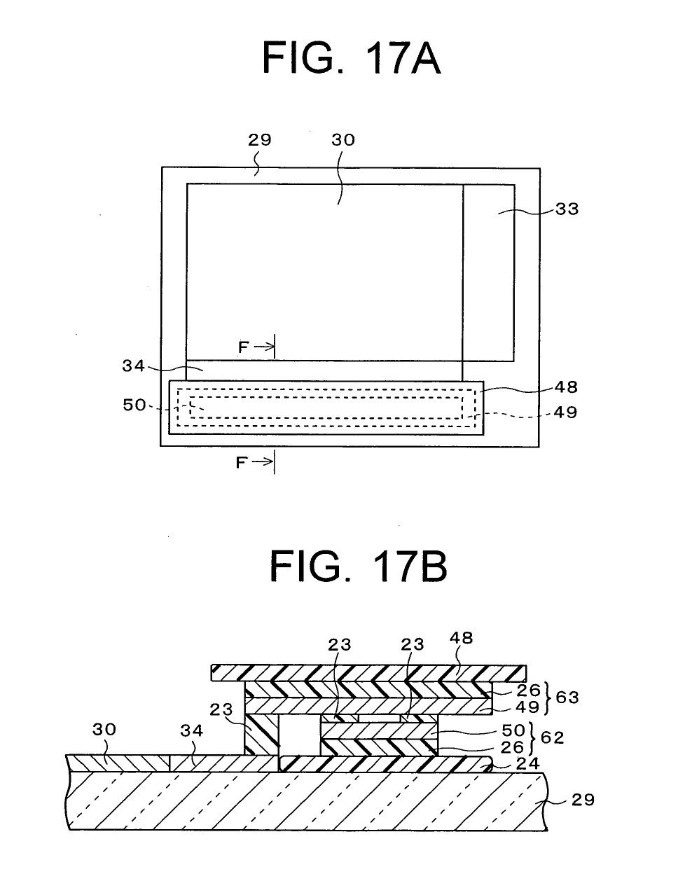

FIG. 17A is a plan view showing a second modification of the semiconductor device according to the fourth embodiment, and FIG. 17B is a cross-sectional view along line F-F shown in FIG. 17A. As shown in FIGS. 17A and 17B, the glass substrate 29 is provided, and the pixel circuit 30, the scan line drive circuit 33 and the data line drive circuit 34 are formed beforehand on the top surface of the glass substrate 29. The scan line drive circuit 33 is provided along one side of the ]pixel circuit 30. The data line drive circuit 34 is provided along one side adjoining the side where the scan line drive circuit 33 is provided. The adhesive layer 24 is provided on the top surface of the glass substrate 29 along the top surface of the data line drive circuit 34, and a flexible control circuit board 62 is mounted on the adhesive layer 24. The flexible control circuit board 62 is provided with the flexible substrate 26 on whose top surface a control circuit 50 is provided. The flexible control circuit board 62 is mounted in such a way that the flexible substrate 26 side contacts the adhesive layer 24. A flexible memory circuit board 63 is mounted on a resin substrate 48. The flexible memory circuit board 63 is provided with the flexible substrate 26 on whose top surface a memory circuit 49 is provided. The flexible memory circuit board 63 is mounted is mounted in such a way that the flexible substrate 26 side contacts the resin substrate 48. The resin substrate 48 on which the flexible memory circuit board 63 is mounted is mounted in such a way as to face the flexible control circuit board 62 mounted on the glass substrate 29. The mating terminal portions (not shown) of the memory circuit 49 and the control circuit 50 are connected together by the conductive resin 23. The mating terminal portions (not shown) of the memory circuit 49 and the data line drive circuit 34 are connected together by the conductive resin 23.

In the thus constructed second modification of the semiconductor device according to the fourth embodiment, a display module having similar functions as those of the display module shown in FIGS. 11A and 11B can be realized by mounting a flexible memory circuit board mounted on the resin substrate 48 on the glass substrate 29 on which the pixel circuit is provided beforehand, thereby ensuring a large degree of freedom of mounting. The other effects of the second modification of the fourth embodiment are the same as those of the fourth embodiment shown in FIG. 15.

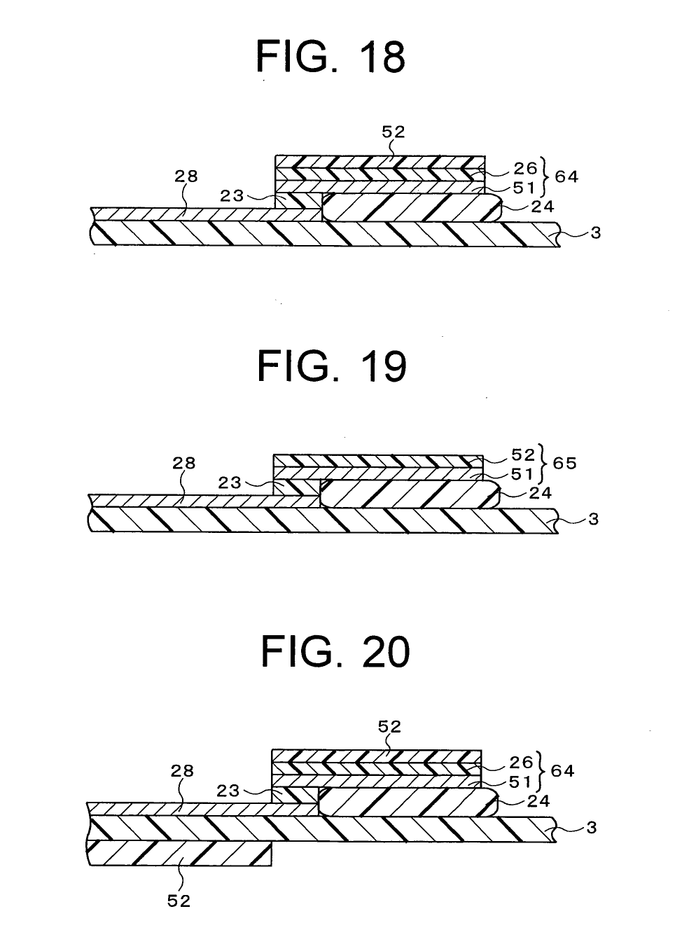

The fifth embodiment of the invention will now be described. FIG. 18 is a cross-sectional view showing a semiconductor device according to the fifth embodiment. As shown in FIG. 18, the semiconductor device of the embodiment is provided with the support substrate 3 on whose top surface the integrated circuit 28 formed directly on a support substrate beforehand is provided. The adhesive layer 24 is provided on the top surface of the support substrate 3, and a flexible integrated circuit board 64 is mounted on the adhesive layer 24. The flexible integrated circuit board 64 is provided with the flexible substrate 26 on whose top surface an integrated circuit 51 is provided. The flexible integrated circuit board 64 is mounted in such a way that the integrated circuit 51 side contacts the adhesive layer 24. The mating terminal portions (not shown) of the integrated circuit 28 directly formed on the support substrate and the integrated circuit 51 are connected together by the conductive resin 23. The flexible substrate 26 side of the flexible integrated circuit board 64 is provided with a high heat conductive film 52 which allows heat generated by the driving of the circuitry to escape. A metal film, such as a copper foil, for example, is used as the high heat conductive film 52.

In the thus constructed semiconductor device according to the fifth embodiment, as shown in FIG. 18, the high heat conductive film 52 having a higher thermal conductivity than the thermal conductivity of 1 W/m*.K of the glass substrate is adhered to the bottom side of the flexible integrated circuit board 64, thereby significantly improving the heat discharge characteristic of the integrated circuit 51. The other effects of the fifth embodiment are the same as those of the second modification of the first embodiment shown in FIGS. 5A to 5C. In the fifth embodiment, a high heat conductive film may be used as a support substrate. A metal film, such as a copper foil, a gold foil or an aluminum foil, can be used as the high heat conductive film 52. Alternatively, a high heat conductive resin film, obtained by dispersing metal or alumina or the like in a PET film, may be used.

FIG. 19 is a cross-sectional view showing a first modification of the semiconductor device according to the fifth embodiment. As shown in FIG. 19, a flexible integrated circuit board 65 having the integrated circuit 51 directly provided on the high heat conductive film 52 is used as the flexible integrated circuit board that is used in the semiconductor device according to the embodiment.

In the first modification of the semiconductor device according to the fifth embodiment with the above-described structure, as the integrated circuit 51 is formed directly on the high heat conductive film 52 which has a flexibility, as shown in FIG. 19, the heat discharge characteristic of the integrated circuit 51 is improved considerably. The other effects of the first modification of the fifth embodiment are the same as those of the fifth embodiment as shown in FIG. 18.

FIG. 20 is a cross-sectional view showing a second modification of the semiconductor device according to the fifth embodiment. As shown in FIG. 20, the high heat conductive film 52 is adhered to the bottom side of the support substrate 3 to ensure an improvement on the heat discharge characteristic of the semiconductor device. The other effects of the second modification of the fifth embodiment are the same as those of the fifth embodiment shown in FIG. 18.

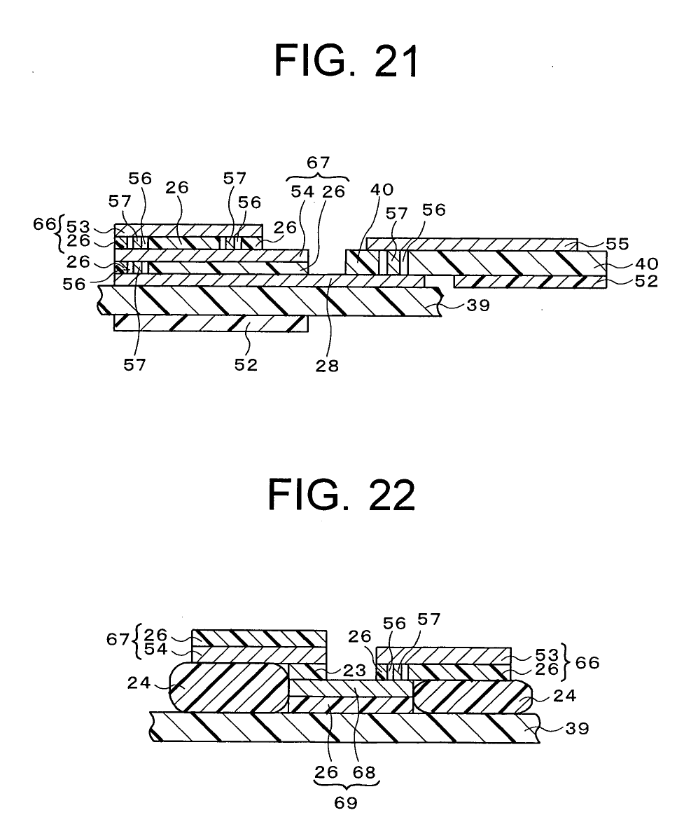

The sixth embodiment of the invention will now be described. FIG. 21 is a cross-sectional view showing a semiconductor device according to the sixth embodiment. As shown in FIG. 21, the semiconductor device of the embodiment is provided with the support substrate 39 on whose top surface the integrated circuit 28 directly formed on the support substrate beforehand is provided. The high heat conductive film 52 is provided at the bottom side of the support substrate 39. The support substrate 40 is also provided, and the integrated circuit 55 directly formed on a support substrate is provided on the top surface of the support substrate 40. The high heat conductive film 52 is provided at the bottom side of the support substrate 40. A through hole 56 is provided at the support substrate 40, and an electric wiring 57 is provided inside the through hole. A flexible integrated circuit board 67 and the support substrate 40 are mounted on the integrated circuit 28 directly formed on a support substrate. The support substrate 40 is mounted in such a way as to partly extend out from the top surface of the integrated circuit 28 directly formed on the support substrate. The integrated circuit 28 directly formed on the support substrate and the integrated circuit 55 directly formed on the support substrate are connected together by the electric wiring 57 in the through hole. The flexible integrated circuit board 67 is provided with the flexible substrate 26 on whose top an integrated circuit 54 is provided. A through hole 56 is provided in the flexible substrate 26, and an electric wiring 57 is provided in the through hole. The integrated circuit 54 and the integrated circuit 28 directly formed on the support substrate are connected together by the electric wiring 57 in the through hole. A flexible integrated circuit board 66 is mounted on the flexible integrated circuit board 67. The flexible integrated circuit board 66 is provided with the flexible substrate 26 on whose top an integrated circuit 53 is provided. A through hole 56 is provided in the flexible substrate 26, and an electric wiring 57 is provided in the through hole. The integrated circuit 53 and the integrated circuit 54 are connected together by the electric wiring 57 in the through hole.

In the semiconductor device according to the sixth embodiment with the above-described structure, as shown in FIG. 21, the integrated circuits laminated one on the other are connected by the electric wiring in the through hole, thereby increasing the degree of freedom of the mounting structure. The other effects of the sixth first embodiment are the same as those of the second modification of the fifth embodiment shown in FIG. 20.

FIG. 22 is a cross-sectional view showing a first modification of the semiconductor device according to the sixth embodiment. As shown in FIG. 22, the support substrate 39 is provided in the first modification of the semiconductor device of the embodiment, and a flexible integrated circuit board 69 is mounted on the top surface of the support substrate 39 with its circuit side facing up. The flexible integrated circuit board 69 is provided with the flexible substrate 26 on whose top surface an integrated circuit 68 is provided. The flexible integrated circuit boards 66 and 67 are mounted on the top surface of the support substrate 39 via respective adhesive layers 24. The flexible integrated circuit board is mounted with the circuit side facing up, and a through hole 56 is provided at the flexible substrate 26, and an electric wiring 57 is provided in the through hole. The integrated circuit 68 and the integrated circuit 53 are connected together by the electric wiring 57 in the through hole. The flexible integrated circuit board 67 is mounted with the circuit side facing down. The integrated circuit 68 and the integrated circuit 54 are connected via the conductive resin 23.

In the first modification of the semiconductor device according to the sixth embodiment with the above-described structure, as shown in FIG. 22, as the method of electrically connecting the laminated integrated circuits, the use of the electric wiring in the through hole, and connecting both laid out with the circuit sides facing each other by the conductive resin are used together, thereby increasing the degree of freedom of the mounting structure. The other effects of the sixth embodiment are the same as those of the second modification of the fifth embodiment shown in FIG. 20.

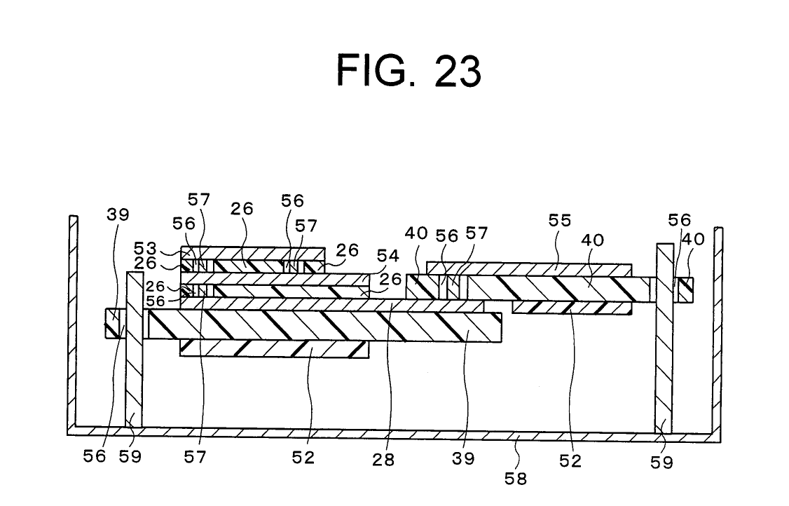

FIG. 23 is a cross-sectional view showing a second modification of the semiconductor device according to the sixth embodiment. In the second modification of the semiconductor device of the embodiment, as shown in FIG. 23, through holes 56 for insertion of a fixing part 59 are respectively provided at the support substrate 39 and the support substrate 40 of the semiconductor device according to the embodiment shown in FIG. 21, and the semiconductor device is secured to a casing 58 by the fixing parts 59.

In the thus constructed second modification of the semiconductor device according to the sixth embodiment, as shown in FIG. 23, the fixing parts are inserted in the through holes and can be secured to the casing of a metal or plastic or the like. The other effects of the sixth embodiment are the same as those of the first modification of the sixth embodiment shown in FIG. 22.

As described above, the lamination of the flexible integrated circuit board, the support substrate and the high heat conductive film or the like can realize a high-performance device excellent in heat discharge characteristic. The structure of the flexible integrated circuit device is not limited to the above-described IC card or display module, and can be modified in various other forms by laying and laminating flexible integrated circuit boards having various functions arbitrarily. In any layout and lamination, the integrated circuit board may be mounted or laminated on the underlying substrate with its circuit side facing up after which electrical connection is made, or the integrated circuit board may be mounted or laminated on the underlying substrate with its circuit side facing down after which electrical connection is made. All the circuit boards need not be flexible integrated circuit boards, but the integrated circuit board which is demanded to have as high a performance as monocrystalline silicon may be an IC chip manufactured from the conventional silicon wafer, or a silicon wafer IC chip substrate and a flexible integrated circuit board may be laid out in combination or laminated in combination. The power supply circuit board can be realized by forming a sheet cell, such as a solar cell, using a polycrystalline semiconductor thin film device.

There may be a desirable case where after the flexible integrated circuit board in the semiconductor device of the invention is connected to the support substrate, its entire surface is covered with a flexible protection sheet or the like of plastic or the like. The support substrate and the flexible substrate may be ones formed of a conductive material, such as a metal, as well as insulative substrates, such as a plastic substrate, a resin substrate and a very thin glass substrate. Alternatively, those substrates may be laminated. A flexible integrated circuit board having various functions can be provided by directly forming CMOS-TFTs or the like on the flexible substrate using a low temperature process, or by transferring TFTs or so, once formed on a high heat-resistive substrate, such as glass, to a flexible substrate. At the time of transferring TFTs or so formed on the glass substrate to a flexible substrate, such as a plastic substrate, the glass substrate, which should be cut thin from the bottom side, can be chemically made thin by etching using a fluorosolution or so. This makes it possible to process a plurality of wafers at a time, thus shortening the process time per wafer. As the glass substrate larger in use can have a larger size than a silicon wafer, a greater number of TFTs or so can be formed on a single substrate. As an IC chip formed on the glass substrate is transparent, it can be used for, for example, a circuit for driving the pixels of a liquid crystal display, thus ensuring a wider range of application. If necessary, TFTS or so which are fabricated from the conventional silicon wafer and transferred on a flexible substrate may be used in combination.

Although the semiconductor devices according to the individual embodiments of the invention are a flexible substrate and a support substrate both provided with integrated circuits on their top surfaces in the foregoing description, the invention is not limited to this type. For example, a flexible substrate and a support substrate provided with passive element circuits having inductors or so formed thereon that attenuate signals of a specific frequency may be used as well.

1. A semiconductor device comprising:
at least one flexible integrated circuit board having
a flexible substrate, and
an integrated circuit provided on said flexible substrate and having an amorphous semiconductor thin film, or a polycrystalline or a monocrystalline semiconductor thin film crystallized by laser annealing; and
a support substrate on which said at least one flexible integrated circuit board is mounted.

2. The semiconductor device according to claim 1, wherein a part or all of said integrated circuit is electrically connected.

3. The semiconductor device according to claim 1, further comprising at least one integrated circuit provided on said support substrate and having an amorphous semiconductor thin film, or a polycrystalline or a monocrystalline semiconductor thin film crystallized by laser annealing.

4. The semiconductor device according to claim 3, wherein said integrated circuit on said flexible substrate and said at least one integrated circuit on said support substrate are electrically connected to each other.

5. The semiconductor device according to claim 1, wherein a part or all of said flexible integrated circuit board is laminated on said support substrate.

6. The semiconductor device according to claim 5, wherein a plurality of flexible integrated circuit boards are laminated and integrated circuits thereof are electrically connected to one another.

7. The semiconductor device according to claim 1, wherein said flexible substrate and/or said support substrate is made of a material selected from a group consisting of organic material, inorganic material and metal material or a mixture of two or more said materials.

8. The semiconductor device according to claim 1, wherein said flexible substrate and/or said support substrate is made of a synthetic resin or a natural resin.

9. The semiconductor device according to claims 1, wherein said flexible substrate and/or said support substrate has a thermal conductivity higher than 1 W/m·K.

10. The semiconductor device according to claim 1, wherein said flexible substrate and/or said support substrate has a layer having a thermal conductivity higher than 1 W/m·K on a side opposite to that side on which said integrated circuit is provided.

11. The semiconductor device according to claim 1, wherein said flexible substrate and said support substrate have through holes where a conductive material is filled to connect two integrated circuits together.

12. The semiconductor device according to claim 1, wherein said flexible substrate and said support substrate have at least one through hole where a fixing member is inserted to fix said flexible substrate and said support substrate to a casing.

13. A semiconductor device comprising:
at least one flexible integrated circuit board having
a flexible substrate, and
an integrated circuit provided on said flexible substrate and having an amorphous semiconductor thin film, or a polycrystalline or a monocrystalline semiconductor thin film crystallized by laser annealing;
at least one first support substrate on which said at least one flexible integrated circuit board is mounted; and
a second support substrate on which said at least one first support substrate is mounted.

14. The semiconductor device according to claim 13, wherein a part or all of said first support substrate is laminated on said second support substrate.

15. The semiconductor device according to claim 13, wherein a part or all of said integrated circuit is electrically connected to each other.

16. The semiconductor device according to claim 13, further comprising at least one integrated circuit provided on said first support substrate and/or said second support substrate and having an amorphous semiconductor thin film, or a polycrystalline or a monocrystalline semiconductor thin film crystallized by laser annealing.

17. The semiconductor device according to claim 16, wherein said integrated circuit on said flexible substrate and said at least one integrated circuit on said first support substrate and/or said second support substrate are electrically connected together.

18. The semiconductor device according to claim 13, wherein all or a part of said flexible integrated circuit board is laminated on said first support substrate.

19. The semiconductor device according to claim 18, wherein a plurality of flexible integrated circuit boards are laminated and integrated circuits thereof are electrically connected to one another.

20. The semiconductor device according to claim 13, wherein said flexible substrate and/or said support substrate is made of a material selected from a group consisting of organic material, inorganic material and metal material or a mixture of two or more said materials.

21. The semiconductor device according to claim 13, wherein said flexible substrate and/or said support substrate is made of a synthetic resin or a natural resin.

22. The semiconductor device according to claim 13, wherein said flexible substrate and/or said support substrate has a thermal conductivity higher than 1 W/m·K.

23. The semiconductor device according to claim 13, wherein said flexible substrate and/or said support substrate has a layer having a thermal conductivity higher than 1 W/m·K on a side opposite to that side on which said integrated circuit is provided.

24. The semiconductor device according to claim 13, wherein said flexible substrate and said support substrate have through holes where a conductive material is filled to connect two integrated circuits together.

25. The semiconductor device according to claim 13, wherein said flexible substrate and said support substrate have at least one through hole where a fixing member is inserted to fix said flexible substrate and said support substrate to a casing.

26. The semiconductor device according to claim 1, wherein said flexible integrated circuit board has a memory circuit for storing data.

27. The semiconductor device according to claim 13, wherein said flexible integrated circuit board has a memory circuit for storing data.

28. The semiconductor device according to claim 1, wherein said flexible integrated circuit board has one circuit selected from a group consisting of a microprocessor circuit which performs numerical operations, a memory circuit storing date, a display pixel circuit which has pixel circuits laid out in a matrix form to display an image, a display periphery drive circuit which controls said display pixel circuit, a power supply circuit which supplies an external circuit with a source voltage, and an antenna circuit which transmits and receives data using electric waves.

29. The semiconductor device according to claim 13, wherein said flexible integrated circuit board has one circuit selected from a group consisting of a microprocessor circuit which performs numerical operations, a memory circuit storing date, a display pixel circuit which has pixel circuits laid out in a matrix form to display an image, a display periphery drive circuit which controls said display pixel circuit, a power supply circuit which supplies an external circuit with a source voltage, and an antenna circuit which transmits and receives data using electric waves.

30. The semiconductor device according to claim 1, further comprising:
a display pixel circuit which has pixel circuits laid out in a matrix form to display an image; and
a display periphery drive circuit which controls said display pixel circuit.

31. The semiconductor device according to claim 13, further comprising:
a display pixel circuit which has pixel circuits laid out in a matrix form to display an image; and
a display periphery drive circuit which controls said display pixel circuit.

32. The semiconductor device according to claim 1, wherein said support substrate has a display pixel circuit which has pixel circuits laid out in a matrix form to display an image, and
said flexible integrated circuit board has a display periphery drive circuit which controls said display pixel circuit.

33. The semiconductor device according to claim 13, wherein said support substrate has a display pixel circuit which has pixel circuits laid out in a matrix form to display an image, and
said flexible integrated circuit board has a display periphery drive circuit which controls said display pixel circuit.

34. The semiconductor device according to claim 28, wherein said display periphery drive circuit is one circuit selected from a group consisting of a scan line drive circuit which sends a scan pulse to said display pixel circuit, a data line drive circuit which sends a video signal to said display pixel circuit, a control circuit which controls operations of said scan line drive circuit and said data line drive circuit, and a memory circuit which stores a signal to control said operations of said scan line drive circuit and said data line drive circuit.

35. The semiconductor device according to claim 29, wherein said display periphery drive circuit is one circuit selected from a group consisting of a scan line drive circuit which sends a scan pulse to said display pixel circuit, a data line drive circuit which sends a video signal to said display pixel circuit, a control circuit which controls operations of said scan line drive circuit and said data line drive circuit, and a memory circuit which stores a signal to control said operations of said scan line drive circuit and said data line drive circuit.

36. The semiconductor device according to claim 13, wherein said second support substrate has a display pixel circuit which has pixel circuits laid out in a matrix form to display an image, and
said first support substrate and/or said flexible integrated circuit board has a display periphery drive circuit which controls said display pixel circuit.
